(19) United States
(12) Patent Application Publication
(10) Pub. No.: US 2023/0396037 A1
(43) Pub. Date: Dec. 7, 2023

(54) TUNABLE MEMS VCSEL WITH EMBEDDED PHOTODETECTOR

(71) Applicant: Meta Platforms Technologies, LLC, Menlo Park, CA (US)

(72) Inventors: Ehsan Vadiee, Bothell, WA (US); Youmin Wang, Bellevue, WA (US); Andrew John Ouderkirk, Kirkland, WA (US); Robert Dale Cavin, Bellevue, WA (US)

(21) Appl. No.: 18/297,259

(22) Filed: Apr. 7, 2023

Related U.S. Application Data
(60) Provisional application No. 63/348,581, filed on Jun. 3, 2022.

(51) Int. Cl. H01S 5/183; H01S 5/125; H01S 5/026

(52) U.S. Cl. CPC H01S 5/18327; H01S 5/125; H01S 5/18369; H01S 5/0262

(57) ABSTRACT

A MEMS-based vertical cavity surface emitting laser (VCSEL) includes an embedded photodiode. A representative VCSEL includes a distributed Bragg reflector (DBR), a photodiode structure located within the distributed Bragg reflector, an active region overlying the distributed Bragg reflector, and a MEMS upper reflector disposed over the active region. The VCSEL may be configured as an optical sensor. The laser cavity and hence a working wavelength of the sensor may be tuned by modulating the MEMS reflector such as through an applied voltage.

### CROSS-REFERENCE TO RELATED APPLICATION

This application claims the benefit of priority under 35 U.S.C. § 119(e) of U.S. Provisional Application No. 63/348,581, filed Jun. 3, 2022, the contents of which are incorporated herein by reference in their entirety.

### BRIEF DESCRIPTION OF THE DRAWINGS

The accompanying drawings illustrate a number of exemplary embodiments and are a part of the specification. Together with the following description, the drawings demonstrate and explain various principles of the present disclosure.

FIG. 1 shows the structure of a MEMS-based VCSEL including a photodiode integrated into a distributed Bragg reflector according to some embodiments.

FIG. 2 is a schematic illustration of a method of manufacturing the MEMS-based VCSEL of FIG. 1 according to some embodiments.

FIG. 3 shows an eye-tracking sensor having an SMI sensor including a tunable VCSEL according to various embodiments.

FIG. 4 is an illustration of exemplary augmented-reality glasses that may be used in connection with embodiments of this disclosure.

FIG. 5 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within this disclosure.

### DETAILED DESCRIPTION OF EXEMPLARY EMBODIMENTS

Various approaches to optical sensing use a heterodyne setup with a coherent light source and a photodetector to sense the distance and velocity of an object based on a frequency modulated continuous wave (FMCW) method. In contrast, self-mixing interferometry (SMI) is a homodyne setup in which the optical sensing occurs in the laser cavity and can be detected in an integrated photodetector without requiring a local oscillator ora separate sensing arm. This can lead to a sensing architecture with low power consumption and a commercially relevant form factor. For example, a SMI-based sensor can be positioned in one or more locations of the frame of a VR/AR headset to estimate the eye movements of a user. The SMI sensor component may include a self-aligned homodyne setup that measures the coherent mixing of reflected light in a laser cavity, where the photodiode measures the modulated light formed in the laser cavity from backscattered light.

A vertical surface-emitting laser (VCSEL) is one type of laser that may be used for depth sensing and may be leveraged in the production of a compact SMI sensor. An approach to sweeping the frequency of a VCSEL (FMCW) uses temperature-induced wavelength tuning, which may lead to a sweeping wavelength range that is limited to a few nanometers due to the inherent small cavity length of the VCSEL. This can reduce the precision/resolution of the SMI sensor. Such a comparative VCSEL design is also limited in tuning range by the free spectral range (FSR). The FSR can be increased by decreasing the optical cavity length, but this will also reduce the wavelength tuning range.

In view of the foregoing, and in an effort to measure the distance/velocity of a user's eye with high resolution (tens of microns), Applicants have developed a VCSEL with a tunable wavelength operating in a single mode. In order to achieve a single wavelength VCSEL with high tunability, an electrostatic MEMS structure can be used in lieu of an upper (lower) DBR in a front (back) emitting structure. This can increase the wavelength tunability to tens of nanometers.

In addition, to reduce phase error, ambient light sensitivity, or the need for a balanced detector structure due to low SNR, a VCSEL epitaxial structure can be modified to incorporate a photodetector to detect power undulations resulting from coherent interference of backscattered light into the laser cavity. The photodetector may be incorporated into the DBR architecture opposite to the MEMS structure. In this case, the VCSEL may act as a broadband tunable source with a single mode that is a coherent mixer, amplifier, and frequency filter suitable for compact sensing architectures.

In accordance with various embodiments, a MEMS-based VCSEL is disclosed having an integrated photodetector that can simultaneously increase the wavelength tunability to more than 10 nm and improve the SNR and phase error. This can significantly increase the depth resolution to sub ^{˜}100 micrometers (depending on the wavelength range).

The disclosed VCSEL may be characterized as a semiconductor laser, and more specifically as a laser diode with a monolithic laser resonator, where the emitted light exits the device in a direction perpendicular to the chip surface. The resonator (cavity) is demarcated by a lower semiconductor Bragg mirror and an upper MEMS structure. Between the Bragg mirror and the MEMS structure there is an active region (i.e., gain structure) formed from a plurality of quantum wells. A total thickness of the active region may be less than approximately 20 micrometers. During operation, the active region may be electrically pumped with a few tens of milliwatts to generate an output power in the range of from approximately 0.5 to 5 mW. A driving current may be applied through a ring electrode, through which the output can be extracted. By applying a voltage to the MEMS architecture, dimensions of the resonator may be adjusted and the operational wavelength of the VCSEL may be tuned. Accurate and precise control of the resonator dimensions may improve the resolution of a VCSEL sensor.

An example VCSEL architecture may include a lower distributed Bragg reflector, a photodiode structure located within the distributed Bragg reflector, an active region overlying the distributed Bragg reflector, and an upper reflector disposed over the active region. A further example VCSEL architecture may include a distributed Bragg reflector having alternating high and low refractive index layers, a photodiode located between a high refractive index layer and a low refractive index layer of the distributed Bragg reflector, an active region overlying the distributed Bragg reflector, and a MEMS reflector disposed over and spaced away from the active region.

A distributed Bragg reflector (DBR) is a mirror structure that may include an alternating sequence of layers of two different optical materials. A distributed Bragg reflector may include alternating high and low refractive index layers, for example. An illustrative DBR design includes a quarter-wave mirror, where each optical layer thickness corresponds to one quarter of the wavelength for which the mirror is designed.

During operation, each interface between the two materials contributes a Fresnel reflection. For the design wavelength, the optical path length difference between reflections from subsequent interfaces is half the wavelength, and the amplitude reflection coefficients for the interfaces have alternating signs, such that the reflected components from the interfaces interfere constructively producing a strong reflection. The achieved reflectance (reflectivity) may be determined by the number of layer pairs and by the refractive index contrast between the layer materials. The reflection bandwidth may be determined by the refractive index contrast. According to certain embodiments, the number of layer pairs may range from 1 to 20 or more.

The DBR layers may include epitaxial layers. As used herein, the terms “epitaxy,” “epitaxial” and/or “epitaxial growth and/or deposition” refer to the nucleation and growth of a layer on a deposition surface where the layer being grown assumes the same crystalline habit as the material of the deposition surface. For example, in an epitaxial deposition process, chemical reactants may be controlled, and the system parameters may be set so that depositing atoms or molecules alight on the deposition surface and remain sufficiently mobile via surface diffusion to orient themselves according to the crystalline orientation of the atoms or molecules of the deposition surface. An epitaxial process may be homogeneous or heterogeneous.

Epitaxial layers within a DBR may or may not be stoichiometric. In accordance with various embodiments, the optical and electrooptical properties of an epitaxial layer may be tuned using doping and related techniques. The introduction of dopants, i.e., impurities, may influence, for example, the highest occupied molecular orbital (HOMO) and lowest unoccupied molecular orbital (LUMO) bands and hence the band gap, induced dipole moment, refractive index and/or polarizability of the material.

Doping may be performed in situ, i.e., during epitaxial growth, or following epitaxial growth, for example, using ion implantation or plasma doping. In exemplary embodiments, doping may be used to modify the electronic structure of an epitaxial layer without damaging the crystal structure. In this vein, a post-implantation annealing step may be used to heal crystal defects introduced during ion implantation or plasma doping. Annealing may include rapid thermal annealing or pulsed annealing, for example.

Doping changes the electron and hole carrier concentrations of a host material at thermal equilibrium. A doped layer may be p-type or n-type. As used herein, “p-type” refers to the addition of impurities that create a deficiency of valence electrons, whereas “n-type” refers to the addition of impurities that contribute free electrons.

Example dopants include Lewis acids (electron acceptors) and Lewis bases (electron donors). Particular examples include charge-neutral and ionic species, e.g., Brønsted acids and Brønsted bases, which in conjunction with the aforementioned processes may be incorporated into a semiconductor by solution growth or co-deposition from the vapor phase. In particular embodiments, a dopant may include an organic molecule, an organic ion, an inorganic molecule, or an inorganic ion. A doping profile may be spatially homogeneous or localized to a particular region (e.g., depth or area) of an epitaxial layer.

The photodiode may include an avalanche photodiode (APD) or a PIN photodiode. A photodiode may include a single layer structure or a multilayer structure. Avalanche photodiodes include high-speed, high sensitivity photodiodes that may be configured to operate using an internal gain mechanism that functions by applying a reverse voltage. Avalanche photodiodes and PIN photodiodes may be adapted to measure low levels of light and may be used in applications that benefit from high sensitivity.

The active region of the VCSEL may include a plurality of quantum wells. The quantum wells are configured to generate photons that travel between the top MEMS structure and the bottom DBR mirror. An example quantum well may include a stacked architecture having a thin gallium arsenide (GaAs) layer sandwiched between two thicker aluminum gallium arsenide (AlGaAs) layers. This structure may additionally contribute to quantum confinement, which may increase the efficiency of the VCSEL.

A MEMS structure may include a tunable optical grating having a plurality of grating structures that are located within the optical transmission path of the VCSEL. A microelectromechanical (MEMS) actuator may be operatively connected to each grating structure for changing ‘the geometry thereof and tuning the grating to a desired wavelength selectivity. In one aspect, the grating structures may include periodic structures that form a Bragg grating.

Also disclosed is a method to increase the precision and accuracy of a self-mixing interferometry sensor in which the VCSEL cavity can be tuned via a MEMS actuator and power undulations can be detected by an integrated photodetector, which may lead to a compact, high gain, and fast optical sensor. This VCSEL design can be used in a SMI architecture. Moreover, the design can be used for optical depth/velocity sensing applications in which high speed and high fidelity are desired.

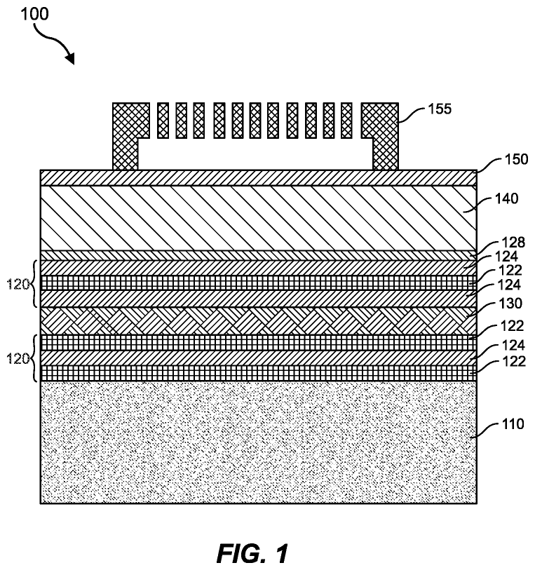

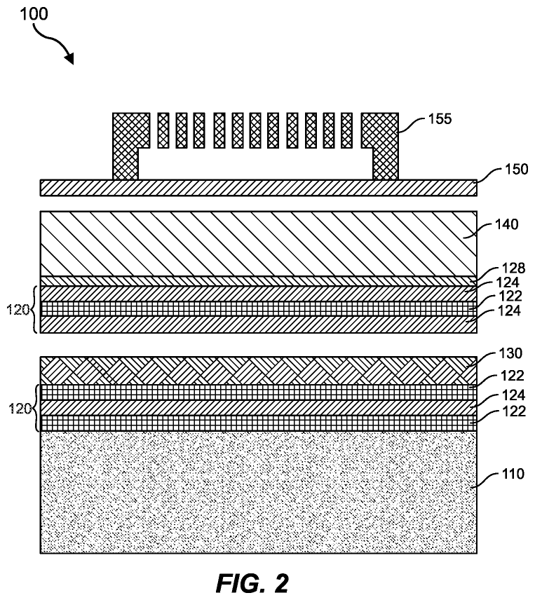

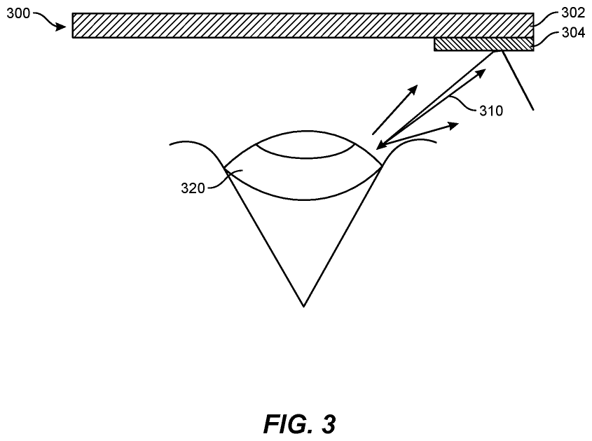

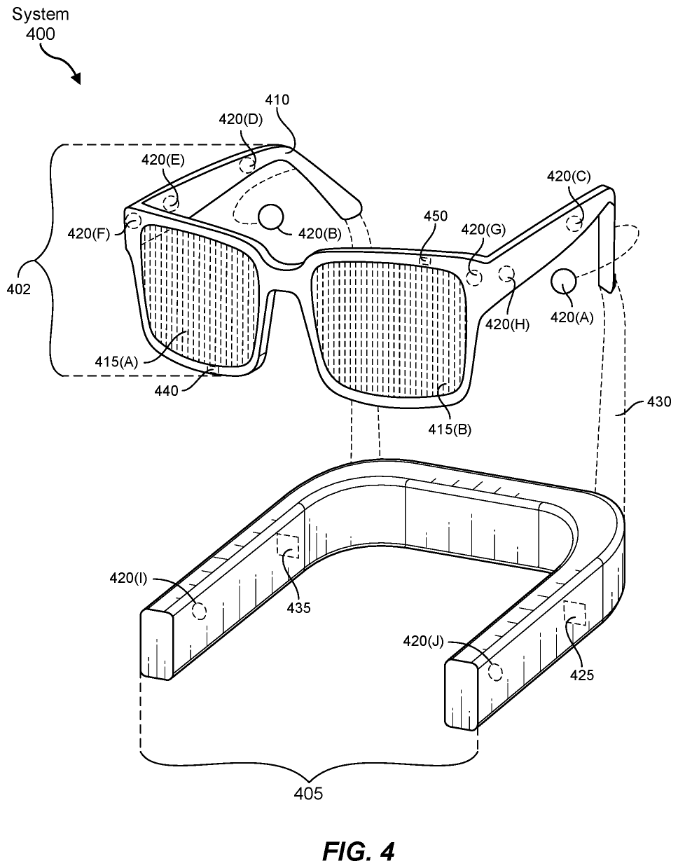

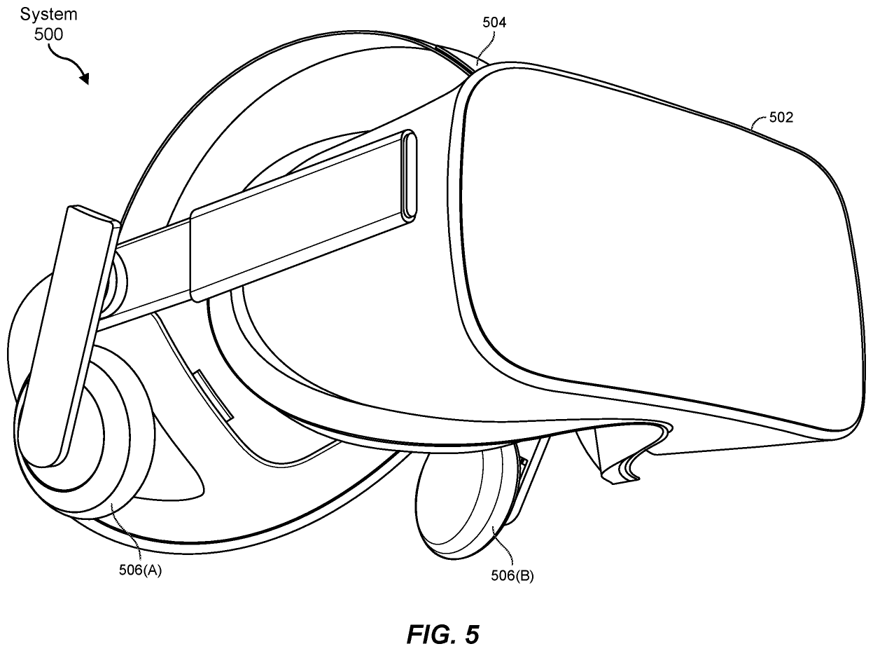

The following will provide, with reference to FIGS. 1-5, a detailed description of MEMS-based VCSEL devices and systems, and their methods of manufacture. The discussion associated with FIGS. 1 and 2 relates to example MEMS-based VCSEL architectures. The discussion associated with FIG. 3 relates to an example eye-tracking sensor including a tunable MEMS-based VCSEL source and sensor. The discussion associated with FIGS. 4 and 5 relates to various virtual reality platforms that may include a MEMS-based VCSEL as described herein.

Referring to FIG. 1, shown is a cross-sectional schematic view of a MEMS-based vertical cavity surface emitting laser (VCSEL) with an integrated photodetector and polarizing surface grating. In the illustrated embodiment, VCSEL 100 includes general structural elements and components and may be utilized, as an example, for various VCSEL array and sensor embodiments as disclosed herein.

Alternating epitaxial layers 122, 124 may be formed over a substrate 110, such as a GaAs substrate. According to some embodiments, single crystal quarter wavelength thick semiconductor layers 122, 124 may be deposited to form an n-type or p-type distributed Bragg reflector (DBR) 120 overlying substrate 110 and underlying a quantum well-based active region 140, which are co-integrated with an overlying MEMS structure 155 to create a laser cavity disposed between mirrors 120, 155. A photodiode 130 may be formed in situ within the DBR 120 or formed separately, stacked, and bonded, e.g., using a flip chip technique.

By way of example, epitaxial layers 122, 124 may be deposited to form an AlGaAs n-DBR 120. Photodiode 130 may include an avalanche photodiode (APD) or a PIN photodiode, for example. A spacer layer 128, such as but not limited to an AlGaAs or AlGaInP spacer, may be formed over an upper surface of DBR 120. A quantum well based active region 140, such as but not limited to an AlGaInP/GaInP or GaAs/AlGaAs multiple quantum well (MQW) active region, may be formed over DBR 120, i.e., directly over spacer layer 128. A MEMS grating 155 may be formed over and at least partially spaced away from a MEMS substrate 150, which may be aligned and bonded to an upper surface of active region 140. That is, MEMS substrate 150 may be bonded directly to an upper surface of active region 140 or to an intervening further spacer layer (not shown).

Although an electrostatic MEMS-based mirror used in lieu of an upper DBR in a front emitting VCSEL is shown in FIG. 1, it will be appreciated that an alternate VCSEL architecture may include an electrostatic MEMS-based mirror used in lieu of a lower DBR in a back emitting structure.

VCSEL 100 is shown in FIG. 2 at an intermediate stage of manufacture. According to the illustrated embodiment, VCSEL 100 may be assembled from plural constituent components, including (a) the MEMS grating 155 and supporting MEMS substrate 150, (b) active region 140 and an upper portion of DBR 120, and (c) photodiode 130 and a lower portion of DBR 120, including substrate 110.

Referring now to FIG. 3, illustrated is an example embodiment of an eye-tracking sensor using an SMI sensor enabled by a tunable VCSEL where the light is guided and shaped by the SMI sensor. Due to the high-speed performance of the MEMS-actuated partially-reflective mirror, the modulation speed can be very high. The partially-reflective mirror can be made of a dielectric polarizing surface grating (PSG), a metallic mirror, or a metasurface, for example.

In the illustrated embodiment, augmented reality system 300 may include a lens 302 and an overmounted tunable VCSEL 304 (e.g., VCSEL 100) located proximate to the eye 320 of a user. VCSEL 304 may be in-field or out-of-field and accordingly located within or peripheral to a viewing aperture of the lens 302. Light projected from VCSEL 304 may be directed to the eye 320 where it may impact one or more of the pupil, iris, and sclera of the eye. Light reflected from the eye 320, such as light ray 310, may be returned to VCSEL 304 where upon reentry into the laser cavity may cause a modulation in the amplitude and/or frequency of emitted light and contribute to a measurement of one or more of distance, speed, or depth according to the principles of self-mixing interferometry.

An optically coherent source system, which can enable high resolution SMI technology, may be characterized by or include: (i) a coherent source that is a tunable VCSEL laser, (ii) an upper reflector that includes a MEMS grating structure that is spaced away from an active layer of the laser, (iii) a MEMS structure that is tuned using electrostatic forces created by an applied voltage, (iv) a MEMS tunable SMI VCSEL architecture as illustrated in FIG. 1, (v) a photodetector integrated into the epitaxial laser structure of a distributed Bragg reflector, (vi) a photodetector positioned inside a lower DBR region, and (vii) a photodetector having various doping structures, including p-n or p-i-n junctions.

Example features of such a system may include (i) a single sensor embodiment with the ability to capture both eye-gaze and a user's own voice (speech), (ii) own voice capture, which may include a clean & denoised version of the user's own voice in the presence of interfering sound, (iii) and eye-gaze that is obtained in real-time using the eye-tracking sensor.

Gaze information can be fed back into audio beamforming algorithms in order to amplify the far-field speech from a specific direction. Beamforming algorithms may use the information captured from multiple microphones distributed across the surface of the headset. This information may be used to create a beam in a specific direction so the information coming from that specific direction can be amplified and other interfering sounds coming from other directions can be attenuated.

As disclosed herein, a tunable VCSEL may be operable as a single mode source. In such a device, an electrostatic MEMS-based mirror can be used in lieu of an upper (lower) DBR in a front (back) emitting structure. This configuration may increase the wavelength tunability to tens of nanometers. In addition, to reduce phase error, ambient light sensitivity, or the need for a balanced detector structure due to low SNR, a VCSEL epitaxial structure can be modified to incorporate a photodetector to detect power undulations resulting from coherent interference of backscattered light into the laser cavity. In this case, the VCSEL may act as a broadband tunable source with a single mode that is a coherent mixer, amplifier, and frequency filter suitable for compact sensing architectures.

### EXAMPLE EMBODIMENTS

Example 1: A vertical cavity surface emitting laser includes a distributed Bragg reflector, a photodiode structure located within the distributed Bragg reflector, an active region overlying the distributed Bragg reflector, and an upper reflector disposed over the active region.

Example 2: The vertical cavity surface emitting laser of Example 1, where the distributed Bragg reflector includes alternating high and low refractive index layers.

Example 3: The vertical cavity surface emitting laser of any of Examples 1 and 2, where the distributed Bragg reflector includes alternating epitaxial layers.

Example 4: The vertical cavity surface emitting laser of any of Examples 1-3, where the distributed Bragg reflector includes alternating layers of gallium nitride and aluminum gallium nitride.

Example 5: The vertical cavity surface emitting laser of any of Examples 1-4, where the photodiode structure is located between a high refractive index layer and a low refractive index layer of the distributed Bragg reflector.

Example 6: The vertical cavity surface emitting laser of any of Examples 1-5, where the photodiode structure includes a p-n junction or a p-i-n junction.

Example 7: The vertical cavity surface emitting laser of any of Examples 1-6, where the photodiode structure includes an avalanche photodiode or a PIN photodiode.

Example 8: The vertical cavity surface emitting laser of any of Examples 1-7, where the active region includes a multiple quantum well active region.

Example 9: The vertical cavity surface emitting laser of any of Examples 1-8, where the active region includes an AlGaInP/GaInP or GaAs/AlGaAs multiple quantum well active region.

Example 10: The vertical cavity surface emitting laser of any of Examples 1-9, where the upper reflector is spaced away from the active region.

Example 11: The vertical cavity surface emitting laser of any of Examples 1-10, where the upper reflector is spaced away from the active region by air gap.

Example 12: The vertical cavity surface emitting laser of any of Examples 1-11, where the upper reflector includes a MEMS grating.

Example 13: The vertical cavity surface emitting laser of any of Examples 1-12, where the upper reflector includes a high contrast grating.

Example 14: The vertical cavity surface emitting laser of any of Examples 1-13, where the upper reflector includes a dielectric polarizing surface grating (PSG) or a metallic mirror.

Example 15: The vertical cavity surface emitting laser of any of Examples 1-14, where a distance between the distributed Bragg reflector and the upper reflector is configured to change in response to a voltage applied to the upper reflector.

Example 16: A vertical cavity surface emitting laser includes a distributed Bragg reflector having alternating high and low refractive index layers, a photodiode located between a high refractive index layer and a low refractive index layer of the distributed Bragg reflector, an active region overlying the distributed Bragg reflector, and a MEMS grating disposed over the active region.

Example 17: The vertical cavity surface emitting laser of Example 16, where the MEMS grating is spaced away from the active region by air gap.

Example 18: The vertical cavity surface emitting laser of any of Examples 16 and 17, where the MEMS grating is configured to be actuated by electrostatic forces created by an applied voltage.

Example 19: A method includes forming a Bragg reflector having alternating epitaxial layers, forming a photodiode between an adjacent pair of the epitaxial layers, forming an active region over the reflector and over the photodiode, forming an optical grating over the active region, and applying a voltage to the optical grating to adjust a cavity length between the Bragg reflector and the optical grating.

Example 20: The method of Example 19, where the optical grating includes a MEMS structure.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 400 in FIG. 4) or that visually immerses a user in an artificial reality (e.g., virtual-reality system 500 in FIG. 5). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 4, augmented-reality system 400 may include an eyewear device 402 with a frame 410 configured to hold a left display device 415(A) and a right display device 415(B) in front of a user's eyes. Display devices 415(A) and 415(B) may act together or independently to present an image or series of images to a user. While augmented-reality system 400 includes two displays, embodiments of this disclosure may be implemented in augmented-reality systems with a single NED or more than two NEDs.

In some embodiments, augmented-reality system 400 may include one or more sensors, such as sensor 440. Sensor 440 may generate measurement signals in response to motion of augmented-reality system 400 and may be located on substantially any portion of frame 410. Sensor 440 may represent a position sensor, an inertial measurement unit (IMU), a depth camera assembly, a structured light emitter and/or detector, or any combination thereof. In some embodiments, augmented-reality system 400 may or may not include sensor 440 or may include more than one sensor. In embodiments in which sensor 440 includes an IMU, the IMU may generate calibration data based on measurement signals from sensor 440. Examples of sensor 440 may include, without limitation, accelerometers, gyroscopes, magnetometers, other suitable types of sensors that detect motion, sensors used for error correction of the IMU, or some combination thereof.

Augmented-reality system 400 may also include a microphone array with a plurality of acoustic transducers 420(A)-420(J), referred to collectively as acoustic transducers 420. Acoustic transducers 420 may be transducers that detect air pressure variations induced by sound waves. Each acoustic transducer 420 may be configured to detect sound and convert the detected sound into an electronic format (e.g., an analog or digital format). The microphone array in FIG. 4 may include, for example, ten acoustic transducers: 420(A) and 420(B), which may be designed to be placed inside a corresponding ear of the user, acoustic transducers 420(C), 420(D), 420(E), 420(F), 420(G), and 420(H), which may be positioned at various locations on frame 410, and/or acoustic transducers 420(I) and 420(J), which may be positioned on a corresponding neckband 405.

In some embodiments, one or more of acoustic transducers 420(A)-(F) may be used as output transducers (e.g., speakers). For example, acoustic transducers 420(A) and/or 420(B) may be earbuds or any other suitable type of headphone or speaker.

The configuration of acoustic transducers 420 of the microphone array may vary. While augmented-reality system 400 is shown in FIG. 4 as having ten acoustic transducers 420, the number of acoustic transducers 420 may be greater or less than ten. In some embodiments, using higher numbers of acoustic transducers 420 may increase the amount of audio information collected and/or the sensitivity and accuracy of the audio information. In contrast, using a lower number of acoustic transducers 420 may decrease the computing power required by an associated controller 450 to process the collected audio information. In addition, the position of each acoustic transducer 420 of the microphone array may vary. For example, the position of an acoustic transducer 420 may include a defined position on the user, a defined coordinate on frame 410, an orientation associated with each acoustic transducer 420, or some combination thereof.

Acoustic transducers 420(A) and 420(B) may be positioned on different parts of the user's ear, such as behind the pinna, behind the tragus, and/or within the auricle or fossa. Or, there may be additional acoustic transducers 420 on or surrounding the ear in addition to acoustic transducers 420 inside the ear canal. Having an acoustic transducer 420 positioned next to an ear canal of a user may enable the microphone array to collect information on how sounds arrive at the ear canal. By positioning at least two of acoustic transducers 420 on either side of a user's head (e.g., as binaural microphones), augmented-reality device 400 may simulate binaural hearing and capture a 3D stereo sound field around about a user's head. In some embodiments, acoustic transducers 420(A) and 420(B) may be connected to augmented-reality system 400 via a wired connection 430, and in other embodiments acoustic transducers 420(A) and 420(B) may be connected to augmented-reality system 400 via a wireless connection (e.g., a Bluetooth connection). In still other embodiments, acoustic transducers 420(A) and 420(B) may not be used at all in conjunction with augmented-reality system 400.

Acoustic transducers 420 on frame 410 may be positioned along the length of the temples, across the bridge, above or below display devices 415(A) and 415(B), or some combination thereof. Acoustic transducers 420 may be oriented such that the microphone array is able to detect sounds in a wide range of directions surrounding the user wearing the augmented-reality system 400. In some embodiments, an optimization process may be performed during manufacturing of augmented-reality system 400 to determine relative positioning of each acoustic transducer 420 in the microphone array.

In some examples, augmented-reality system 400 may include or be connected to an external device (e.g., a paired device), such as neckband 405. Neckband 405 generally represents any type or form of paired device. Thus, the following discussion of neckband 405 may also apply to various other paired devices, such as charging cases, smart watches, smart phones, wrist bands, other wearable devices, hand-held controllers, tablet computers, laptop computers, other external compute devices, etc.

As shown, neckband 405 may be coupled to eyewear device 402 via one or more connectors. The connectors may be wired or wireless and may include electrical and/or non-electrical (e.g., structural) components. In some cases, eyewear device 402 and neckband 405 may operate independently without any wired or wireless connection between them. While FIG. 4 illustrates the components of eyewear device 402 and neckband 405 in example locations on eyewear device 402 and neckband 405, the components may be located elsewhere and/or distributed differently on eyewear device 402 and/or neckband 405. In some embodiments, the components of eyewear device 402 and neckband 405 may be located on one or more additional peripheral devices paired with eyewear device 402, neckband 405, or some combination thereof.

Pairing external devices, such as neckband 405, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 400 may be provided by a paired device or shared between a paired device and an eyewear device, thus reducing the weight, heat profile, and form factor of the eyewear device overall while still retaining desired functionality. For example, neckband 405 may allow components that would otherwise be included on an eyewear device to be included in neckband 405 since users may tolerate a heavier weight load on their shoulders than they would tolerate on their heads. Neckband 405 may also have a larger surface area over which to diffuse and disperse heat to the ambient environment. Thus, neckband 405 may allow for greater battery and computation capacity than might otherwise have been possible on a stand-alone eyewear device. Since weight carried in neckband 405 may be less invasive to a user than weight carried in eyewear device 402, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 405 may be communicatively coupled with eyewear device 402 and/or to other devices. These other devices may provide certain functions (e.g., tracking, localizing, depth mapping, processing, storage, etc.) to augmented-reality system 400. In the embodiment of FIG. 4, neckband 405 may include two acoustic transducers (e.g., 420(I) and 420(J)) that are part of the microphone array (or potentially form their own microphone subarray). Neckband 405 may also include a controller 425 and a power source 435.

Acoustic transducers 420(I) and 420(J) of neckband 405 may be configured to detect sound and convert the detected sound into an electronic format (analog or digital). In the embodiment of FIG. 4, acoustic transducers 420(I) and 420(J) may be positioned on neckband 405, thereby increasing the distance between the neckband acoustic transducers 420(I) and 420(J) and other acoustic transducers 420 positioned on eyewear device 402. In some cases, increasing the distance between acoustic transducers 420 of the microphone array may improve the accuracy of beamforming performed via the microphone array. For example, if a sound is detected by acoustic transducers 420(C) and 420(D) and the distance between acoustic transducers 420(C) and 420(D) is greater than, e.g., the distance between acoustic transducers 420(D) and 420(E), the determined source location of the detected sound may be more accurate than if the sound had been detected by acoustic transducers 420(D) and 420(E).

Controller 425 of neckband 405 may process information generated by the sensors on neckband 405 and/or augmented-reality system 400. For example, controller 425 may process information from the microphone array that describes sounds detected by the microphone array. For each detected sound, controller 425 may perform a direction-of-arrival (DOA) estimation to estimate a direction from which the detected sound arrived at the microphone array. As the microphone array detects sounds, controller 425 may populate an audio data set with the information. In embodiments in which augmented-reality system 400 includes an inertial measurement unit, controller 425 may compute all inertial and spatial calculations from the IMU located on eyewear device 402. A connector may convey information between augmented-reality system 400 and neckband 405 and between augmented-reality system 400 and controller 425. The information may be in the form of optical data, electrical data, wireless data, or any other transmittable data form. Moving the processing of information generated by augmented-reality system 400 to neckband 405 may reduce weight and heat in eyewear device 402, making it more comfortable to the user.

Power source 435 in neckband 405 may provide power to eyewear device 402 and/or to neckband 405. Power source 435 may include, without limitation, lithium ion batteries, lithium-polymer batteries, primary lithium batteries, alkaline batteries, or any other form of power storage. In some cases, power source 435 may be a wired power source. Including power source 435 on neckband 405 instead of on eyewear device 402 may help better distribute the weight and heat generated by power source 435.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 500 in FIG. 5, that mostly or completely covers a user's field of view. Virtual-reality system 500 may include a front rigid body 502 and a band 504 shaped to fit around a user's head. Virtual-reality system 500 may also include output audio transducers 506(A) and 506(B). Furthermore, while not shown in FIG. 5, front rigid body 502 may include one or more electronic elements, including one or more electronic displays, one or more inertial measurement units (IMUS), one or more tracking emitters or detectors, and/or any other suitable device or system for creating an artificial reality experience.

Artificial-reality systems may include a variety of types of visual feedback mechanisms. For example, display devices in augmented-reality system 400 and/or virtual-reality system 500 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 400 and/or virtual-reality system 500 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented-reality system 400 and/or virtual-reality system 500 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 5, output audio transducers 506(A) and 506(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 4, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a DBR layer that comprises or includes gallium nitride include embodiments where a DBR layer consists essentially of gallium nitride and embodiments where a DBR layer consists of gallium nitride.

What is claimed is:

1. A vertical cavity surface emitting laser comprising:
a distributed Bragg reflector;
a photodiode structure located within the distributed Bragg reflector;
an active region overlying the distributed Bragg reflector; and
an upper reflector disposed over the active region.

2. The vertical cavity surface emitting laser of claim 1, wherein the distributed Bragg reflector comprises alternating high and low refractive index layers.

3. The vertical cavity surface emitting laser of claim 1, wherein the distributed Bragg reflector comprises alternating epitaxial layers.

4. The vertical cavity surface emitting laser of claim 1, wherein the distributed Bragg reflector comprises alternating layers of gallium nitride and aluminum gallium nitride.

5. The vertical cavity surface emitting laser of claim 1, wherein the photodiode structure is located between a high refractive index layer and a low refractive index layer of the distributed Bragg reflector.

6. The vertical cavity surface emitting laser of claim 1, wherein the photodiode structure comprises a p-n junction or a p-i-n junction.

7. The vertical cavity surface emitting laser of claim 1, wherein the photodiode structure comprises an avalanche photodiode or a PIN photodiode.

8. The vertical cavity surface emitting laser of claim 1, wherein the active region comprises a multiple quantum well active region.

9. The vertical cavity surface emitting laser of claim 1, wherein the active region comprises an AlGaInP/GaInP or GaAs/AlGaAs multiple quantum well active region.

10. The vertical cavity surface emitting laser of claim 1, wherein the upper reflector is spaced away from the active region.

11. The vertical cavity surface emitting laser of claim 1, wherein the upper reflector is spaced away from the active region by air gap.

12. The vertical cavity surface emitting laser of claim 1, wherein the upper reflector comprises a MEMS grating.

13. The vertical cavity surface emitting laser of claim 1, wherein the upper reflector comprises a high contrast grating.

14. The vertical cavity surface emitting laser of claim 1, wherein the upper reflector comprises a dielectric polarizing surface grating (PSG) or a metallic mirror.

15. The vertical cavity surface emitting laser of claim 1, wherein a distance between the distributed Bragg reflector and the upper reflector is configured to change in response to a voltage applied to the upper reflector.

16. A vertical cavity surface emitting laser comprising:
a distributed Bragg reflector comprising alternating high and low refractive index layers;
a photodiode located between a high refractive index layer and a low refractive index layer of the distributed Bragg reflector;
an active region overlying the distributed Bragg reflector; and
a MEMS grating disposed over the active region.

17. The vertical cavity surface emitting laser of claim 16, wherein the MEMS grating is spaced away from the active region by air gap.

18. The vertical cavity surface emitting laser of claim 16, wherein the MEMS grating is configured to be actuated by electrostatic forces created by an applied voltage.

19. A method comprising:
forming a Bragg reflector comprising alternating epitaxial layers;
forming a photodiode between an adjacent pair of the epitaxial layers;
forming an active region over the reflector and over the photodiode;
forming an optical grating over the active region; and
applying a voltage to the optical grating to adjust a cavity length between the Bragg reflector and the optical grating.

20. The method of claim 19, wherein the optical grating comprises a MEMS structure.
